(19) United States
(12) Patent Application Publication
(10) Pub. No.: US 2009/0040736 A1
(43) Pub. Date: Feb. 12, 2009

(54) Multi-part circuit board

(75) Inventors: Frank Becherer, Haslach (DE); Winfried Rauer, Fischerbach (DE); Ralf Koernle, Zell a. H. (DE)

Correspondence Address: THE NATH LAW GROUP, 112 South West Street, Alexandria, VA, 22314, US

(73) Assignee: VEGA Grieshaber KG, Wolfach (DE)

(21) Appl. No.: 12/222,072

(22) Filed: Aug. 4, 2008

Related U.S. Application Data
(60) Provisional application No. 60/935,814, filed on Aug. 31, 2007.

(30) Foreign Application Priority Data
Aug. 10, 2007 (DE) 10 2007 038 054.4

(51) Int. Cl. H05K 1/14

(52) U.S. Cl. 361/749

(57) ABSTRACT

Multi-part circuit board comprising at least two partial boards (1, 2, 3, 4) and flexible signal lines (7), wherein at least one clamping element (10), which can be inserted into at least one clamping opening (12) of another partial board (4), is integrally molded onto at least one partial board (1).

The invention relates to a multi-part circuit board according to the features specified in the preamble of claim 1.

Multi-part printed circuit boards are known in the state of the art in order to accommodate larger scale circuit configurations in, e.g., cylindrically shaped housings. Such a multi-part circuit board consists of a plurality partial boards that are connected to each other through flexible signal connections, such as ribbon cables, and is bent-in between the partial boards in its application configuration so that, e.g. a four-sided hollow cylinder is formed, which can be inserted into the cylindrically shaped housing. To fasten the individual partial boards in a selected position with respect to each other, it is usual in the state of the art to glue the individual partial boards or to fasten them relative to each other using additional accessories such as connectors or frames. For example, PCB spacers, which enable multi-part circuit boards to be fastened at a particular distance to each other, are known from the company Skiffy.

The disadvantage to such possibilities for interconnection is that fastening by means of connectors or frames leads to additional production steps for assembling these accessories as well as corresponding costs for the accessories. In the case where the printed circuit boards are glued to each other, problems can moreover arise due to chemical reactions between the adhesive and other sealing compounds or the circuit boards.

This is time-consuming and cost-intensive and introduces other sources of error and/or problems.

It is the objective of the invention to provide a multi-part circuit board with which it is possible to fasten two or more printed circuit boards to one another in a selected position without using additional assembly components. Moreover, a faster and more advantageous assembly of the multi-part circuit board should be possible.

This objective is achieved by a multi-part circuit board having the features of claim 1.

The multi-part circuit board according to the invention has at least two partial boards and flexible connections located between them, with at least one clamping element, which can be inserted into at least one clamping opening of another partial board, being integrally molded onto a first partial board.

Through a development of the multi-part circuit board according to the invention, it is possible to fasten two partial boards to each other without the need for additional assembly components or gluing. A short assembly time and increased temperature resistance of the clamp connection in comparison with, e.g., adhesive connections are advantageous in this type of development.

In a preferred embodiment of the invention, the clamping opening is embodied as a clamping slit and the clamping element is integrally molded onto the partial board in one-piece, preferably laterally, and consists of the circuit board material. In this preferred embodiment variant, it is particularly advantageous that it is possible to produce the circuit board and clamping element in one step and that the fastening can take place in a simple manner.

According to another preferred embodiment, a plurality of, especially two, clamping catches and clamping slits are provided. The advantage of this type of embodiment is that a parallel arrangement of a plurality of clamping catches along one edge of the circuit board ensures that the circuit boards are fastened to each other in a non-rotating manner.

It is particularly advantageous if there are four partial boards, which have side edges running parallel to each other, and if the flexible connections are configured embodied as connecting lines and/or signal lines. An embodiment of this invention is preferably employed in a multi-part circuit board having four partial boards, because the partial boards stand in their preferred position at a 90° angle with respect to each other and a particularly effective fastening by means of an arrangement with clamping catches and clamping slits is thereby achieved.

Advantageous embodiments of the invention and further developments are subject matter of the dependent claims.

The invention will be explained below on the basis of an example embodiment with reference to the attached figures.

The drawing shows:

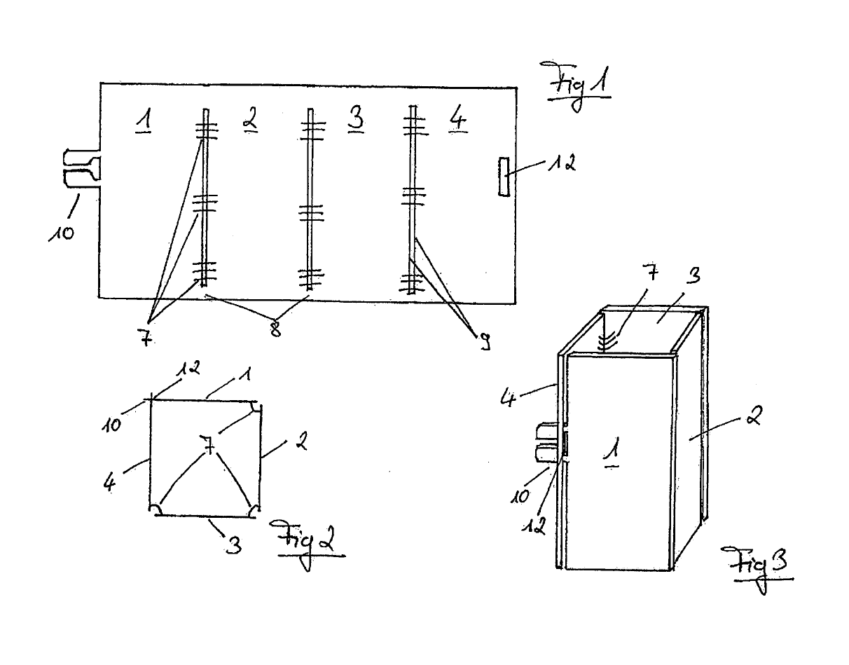

FIG. 1 a top view on a multi-part circuit board according to the invention in its initial configuration,

FIG. 2 a top view on a multi-part circuit board in its assembly configuration and

FIG. 3 a perspective view of the foldable circuit boards from FIGS. 1 and 2 in their assembly configuration.

FIG. 1 shows an example embodiment of a multi-part circuit board according to the invention in its initial configuration. The multi-part circuit board consists of four partial boards 1, 2, 3, 4 which are rigidly connected to each other in the initial configuration. In this state, components are mounted on the multi-part circuit board, and the multi-part circuit board is processed up to its full operability and then tested. Following a successful test, the multi-part circuit board is subdivided into the partial boards 1, 2, 3, 4 at the separation points 8 and can then be brought into its application configuration. A clamping catch 10, which can be inserted into a clamping slit 12 of a fourth circuit board 4 of the multi-part circuit board, is integrally molded onto a first partial board 1 of a multi-part circuit board. The individual partial boards 1, 2, 3, 4 preferably have edges 9 running in parallel so that the application configuration the multi-part circuit board, as shown in FIGS. 2 and 3, has the shape of a four-sided hollow cylinder. Flexible connecting lines 7, which can conduct electrical signals between the partial boards 1, 2, 3, 4 on the one hand and serve as a flexible connection for the partial boards 1, 2, 3, 4 on the other hand, are located between the partial boards 1, 2, 3, 4. The clamping catch 10 is integrally shaped as a laterally slotted spring element comprising a first leg 10a and a second leg 10b. A clamping effect is achieved in that the clamping catch 10 is dimensioned somewhat larger than the clamping slit 12. When the clamping catch 10 is inserted into the clamping slit 12, the first leg 10a and the second leg 10b of the clamping catch 10 will move toward each other and clamp into the clamping slit 12. The front edges of the legs 10a, 10b are chamfered to assure that the clamping catch 10 can be more easily inserted into the clamping slit 12.

FIG. 2 shows a top view of the multi-part circuit board of FIG. 1 in its application configuration. As shown in FIG. 2, in the application configuration, the multi-part circuit board has a cross section in the shape of a square. The individual partial boards 1, 2, 3, 4 are respectively located on the side surfaces of the square. The clamping catch 10 of the first partial board 1 is inserted into the clamping slit 12 of the fourth partial board 4 so that this clamping connection establishes the alignment of the first partial board 1 with respect to the fourth partial board 4 at a 90° angle and determines the alignment of the second partial board 2 and the third partial board 3. As shown in FIG. 2, the clamping connection connects the first partial board 1 and the fourth partial board 4, while flexible signal connections 7 connect the other partial boards 1, 2, 3, 4 to each other.

FIG. 3 shows a perspective view of the multi-part circuit board in its application configuration. The basic square shape of the multi-part circuit board and the clamping connection between the first partial board 1 and the fourth partial board 4 by means of the clamping catch, 10 which is guided through the clamping slit 12, are clearly evident in this depiction.

### List of Reference Characters

1 First circuit board
2 Second circuit board
3 Third circuit board
4 Fourth circuit board
7 Connecting lines
8 Separation points
9 Edges
10 Clamping element/clamping catch
10a First leg
10b Second leg
12 Clamping opening/clamping slit

1. Multi-part circuit board comprising at least two partial boards (1, 2, 3, 4) and flexible connecting lines (7),
characterized in that at least one clamping element (10), which can be inserted into at least one clamping opening (12) of another partial board (4), is integrally molded onto at least one partial board (1).

2. Multi-part circuit board according to claim 1,
characterized in that the clamping opening is embodied as a clamping slit (12).

3. Multi-part circuit board according to claim 1,
characterized in that the clamping element (10) is of one-piece integral construction with the partial board (1).

4. Multi-part circuit board according to claim 1,
characterized in that the clamping element is integrally molded laterally onto the partial board as a clamping catch (10).

5. Multi-part circuit board according to claim 1,
characterized in that the clamping catch (10) is made of the circuit board material.

6. Multi-part circuit board according to claim 1,
characterized in that two clamping catches (10) and two clamping slits (12) are provided.

7. Multi-part circuit board according claim 1,
characterized in that the partial boards (1, 2, 3, 4) have edges (9) running in parallel.

8. Multi-part circuit board according to claim 1,
characterized in that four partial boards (1, 2, 3, 4) are provided.

9. Multi-part circuit board according to claim 1,
characterized in that the flexible connections (7) are embodied as connecting lines and/or signal lines.
